(19) United States
(12) Patent Application Publication
(10) Pub. No.: US 2012/0068761 A1
(43) Pub. Date: Mar. 22, 2012

(54) Method and apparatus for protection of an anti-fuse element in a high-voltage integrated circuit

(75) Inventor: Sujit Banerjee, San Jose, CA (US)

(73) Assignee: Power Integrations, Inc., San Jose, CA (US)

(21) Appl. No.: 12/807,974

(22) Filed: Sep. 17, 2010

(51) Int. Cl. H01H 85/02; H01L 29/788

(52) U.S. Cl. 327/525; 257/355; 257/E29.302

(57) ABSTRACT

A soft clamp semiconductor device for preventing inadvertent programming of an unselected anti-fuse (AF) element comprises a MOSFET which includes a first well region disposed in a substrate. Source and drain regions are disposed in the first well region, the drain region being electrically coupled to the first capacitive plate of the AF element and the source region being electrically coupled to a second capacitive plate of the AF element. An insulated gate is disposed over a channel area of the first well region that separates the drain and source regions. A gate capacitance of the MOSFET is substantially less than a capacitance of the unselected AF element such that when a programming voltage is applied to the first capacitive plate, a current flows through the MOSFET that charges the second capacitive plate, thereby reducing a voltage build-up across the unselected AF element.

### TECHNICAL FIELD

The present disclosure generally relates to an anti-fuse element in a high-voltage integrated circuit. In particular, a method and apparatus for protecting an anti-fuse element against unintentional programming.

### BACKGROUND

A common type of integrated circuit (IC) device is a metal-oxide-semiconductor field effect transistor (MOSFET) that includes a source region, a drain region, and a channel region. In high voltage applications, a high voltage MOSFET known as an HVFET (high voltage field effect transistor) maybe used. The high voltage IC device typically includes a controller circuit that operates on low voltage (0 V-12 V) that is separated from the HVFET by a ‘tap’ structure. The internal circuitry of the device is typically limit-protected from the high externally-applied voltage by the “tap” structure. For example, when the drain of the HVFET is taken to, say 550 V, the tap transistor limits the maximum voltage exposed to internal circuitry to approximately 50 V.

The operating characteristics of an IC are typically set by a process known as trimming. In particular, trimming typically occurs to adjust certain operating characteristics back to within their required tolerances. The process of trimming may involve selectively closing (or opening) one or more electrical elements that indicates to the controller to adjust certain operating characteristics of the high voltage IC. In one example, the anti-fuses used for trimming may be capacitors.

During the process of trimming anti-fuses that are capacitors, a voltage greater than the breakdown voltage of the capacitor may be applied to program the anti-fuse. In this manner, an operating characteristic of the IC is adjusted and indicates an initial condition of the integrated circuit. In certain trimming circuits, several anti-fuse elements may be coupled in parallel and share a same voltage bus. During the trimming process, the anti-fuse elements, which may be capacitors, may be coupled in series with a switch. When the switch corresponding to a particular capacitor is turned on, a breakdown voltage is applied to the voltage bus sufficient to program the capacitor and complete the trimming of that particular anti-fuse. However, other anti-fuse elements connected to the voltage bus may be exposed to the breakdown voltage. This could allow an inadvertent voltage to be applied across a non-selected anti-fuse due to parasitic capacitances associated with the switch coupled in series with each anti-fuse element.

### BRIEF DESCRIPTION OF THE DRAWINGS

The present disclosure will be understood more fully from the detailed description that follows and from the accompanying drawings, which however, should not be taken to limit the invention to the specific embodiments shown, but are for explanation and understanding only.

FIG. 1 illustrates an example high voltage IC device including an anti-fuse circuit coupled to a soft clamp circuit.

FIG. 2 illustrates an example anti-fuse voltage in the absence of a soft clamp circuit during a trimming operation.

FIG. 3 illustrates an example voltage across an anti-fuse voltage in the presence of a soft clamp circuit during a trimming operation.

FIG. 4 illustrates an example cross-section of a soft clamp device structure.

### DESCRIPTION OF EXAMPLE EMBODIMENTS

A method and apparatus for programming an anti-fuse element of a power IC is disclosed. In the following description specific details are set forth, voltages, structural features, manufacturing steps, etc., in order to provide a thorough understanding of the disclosure herein. However, persons having ordinary skill in the relevant arts will appreciate that these specific details may not be needed to practice the embodiments described. References throughout this description to “one embodiment”, “an embodiment”, “one example” or “an example” means that a particular feature, structure or characteristic described in connection with the embodiment or example is included in at least one embodiment. The phrases “in one embodiment”, “in an embodiment”, “one example” or “an example” in various places throughout this description are not necessarily all referring to the same embodiment or example. Furthermore, the particular features, structures or characteristics may be combined in any suitable combinations and/or sub-combinations in one or more embodiments or examples.

It should be understood that the elements in the figures are representational, and are not drawn to scale in the interest of clarity. It is also appreciated that although an IC utilizing mostly N-channel transistor devices (both high-voltage and low-voltage) are disclosed, P-channel transistors may also be fabricated by utilizing the opposite conductivity types for all of the appropriate doped regions.

In the context of the present application a high-voltage or power transistor is any semiconductor transistor structure that is capable of supporting 150 volts or more in an “off” state or condition. In one embodiment, a power switch is a high voltage field effect transistor (HVFET) illustrated as an N-channel metal oxide semiconductor field-effect transistor (MOSFET) with the high-voltage being supported between the source and drain regions. In other embodiments, a power switch may comprise a bipolar junction transistor (BJT), an insulated gate field effect transistor (IGFET), or other device structures that provide a transistor function.

For purposes of this disclosure, “ground” or “ground potential” refers to a reference voltage or potential against which all other voltages or potentials of a circuit or IC are defined or measured. A “pin” provides a point of external electrical connection to an IC device or package, thereby allowing external components, circuits, signals, power, loads, etc., to be coupled to the internal components and circuitry of a high voltage IC.

It is further appreciated within the context of this disclosure that a ‘high’ voltage is defined as a voltage that is substantially 150 V or greater, a ‘medium’ voltage is defined between 150 V and 50 V, and a ‘low’ voltage is defined to be less than 12 V.

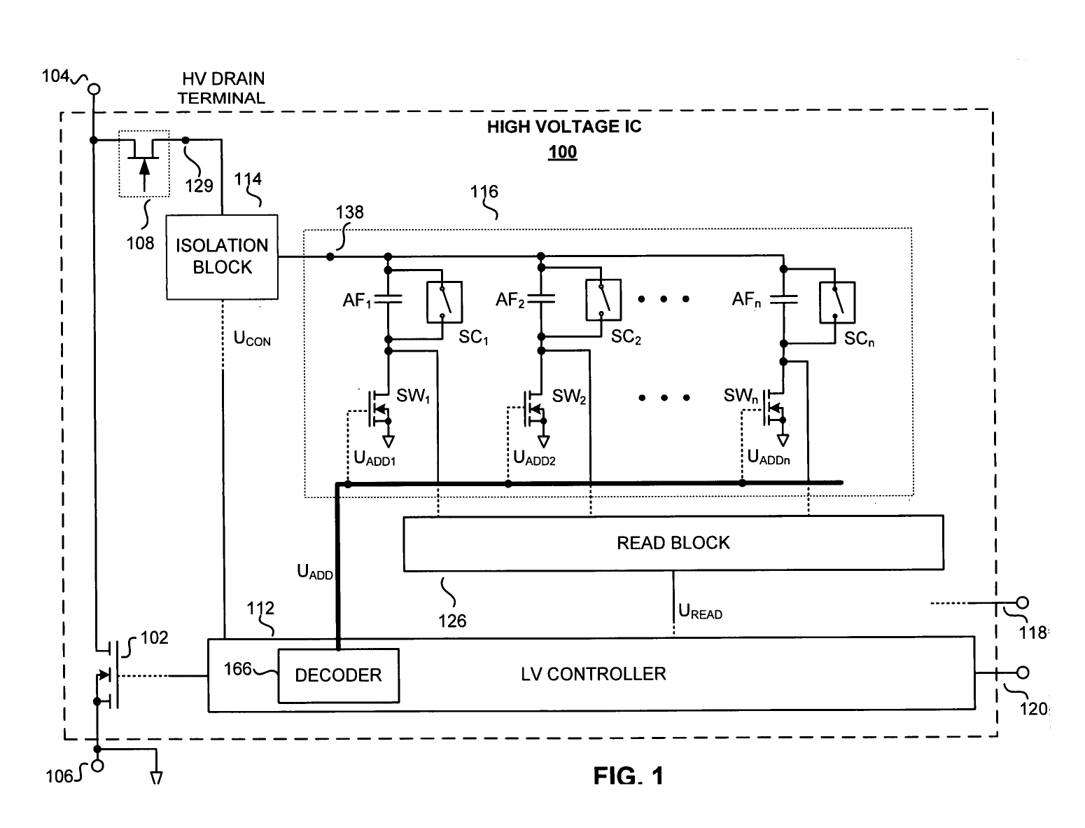

As shown, FIG. 1 is a block diagram illustrating an example high voltage IC 100 including a high voltage (HV) switch 102 that may be representative of a high voltage field effect transistor (HVFET), a high voltage (HV) drain terminal 104, a source terminal 106, a tap element 108, a low voltage (LV) controller 112, an isolation block 114, a trimming circuit block 116, a supply terminal 118, a feedback terminal 120, and a read block 126. As shown, high voltage switch 102 is coupled between HV drain terminal 104 and source terminal 106. In one example, high voltage switch 102 may be used in a power supply to control the current through the primary winding of an energy transfer element, such as a coupled inductor. In operation, HV drain terminal 104 is typically coupled to receive input from an external circuit (not shown).

As further shown, a source terminal 106 is coupled to another end of HV switch 102. A tap element 108 is coupled to HV drain terminal 104. In operation, tap element 108 provides a buffer between circuitry in high voltage IC 100 and HV drain terminal 104. In one embodiment, tap element 108 comprises a junction field-effect transistor (JFET). In operation, tap element 108 provides a buffer between HV terminal 104 and internal circuitry in high voltage IC that may only be exposed to lower voltages. For example, during normal operation HV terminal 104 may be exposed to voltages in excess of 550 V where as the pinch-off voltage (voltage at a node 129) is no more than 50 V. In this manner, tap element 108 provides a buffer and prevents other internal elements in high voltage IC 100 from being rated at significantly high voltages which translates into a smaller high voltage IC 100.

In one example, HV IC 100, tap element 108 may include a tap transistor structure that protects circuitry in high voltage IC from voltage greater than approximately 50 V. For example, when the voltage at high (HV) terminal 104 is taken to, say 550 V, the tap transistor limits the maximum voltage at node 129 to approximately 50 V. In normal operating conditions, isolation block 114 isolates trimming circuit block 116 from the voltage appearing at a node 129.

As shown, trimming circuit block 116 is coupled to HV drain terminal 104 through isolation block 114. Practitioners will appreciate that isolation block 114 functions to isolate trimming block 116 from medium voltage produced by tap element 108 at node 129 under normal operating conditions.

During a trimming or programming operation, trimming circuit block 116 allows for a trimming process of high voltage IC 100. More specifically, trimming may involve selectively closing (or opening) one or more electrical elements that indicates to the controller to adjust certain operating characteristics of the high voltage IC. In one example, trimming process may be done on high voltage IC 100 to assure certain performance specifications. In the context of the present disclosure, trimming is a process of writing or programming an anti-fuse in response to setting certain operating characteristics of high voltage IC 100.

In one example, trimming block 116 consists of a series or array of anti-fuses AFₙ. In accordance with the present disclosure, an anti-fuse is a circuit element that provides a normally open electrical connection in a device structure like that of a capacitor, with two or more layers of metal, polysilicon, or doped semiconductor material separated by a dielectric layer (e.g., oxide, nitride, etc.). The electrical connection between the two layers can be permanently closed by applying a large voltage across two conductors which acts to break down or destroy the dielectric layer, thereby electrically programming the two metal layers. In one embodiment, each anti-fuse AF of trimming circuit block 116 comprises a tiny area of gate oxide, ˜10 μm².

As shown, trimming circuit block 116 includes a series of selector switches SWₙ that are electrically coupled in series with individually corresponding anti-fuses AF_{N} included in trimming circuit block 116. Each anti-fuse AF_{N} is coupled between node 138 and a corresponding selector switch (SW). Prior to programming (i.e., trimming), anti-fuses AFₙ do not pass any current; that is, it appears as an open circuit to a normal D.C. operating voltage (e.g., VDD=5-6 V).

As shown, selector switches SWₙ are coupled in series with corresponding anti-fuse AFₙ. A selector switch may be any type of transistor or switch that allows current to pass through its corresponding anti-fuse. During a trimming operation, certain selector switches SWₙ of trimming circuit block 116 may be activated (one at a time) to allow a medium voltage (e.g., 50 V) to be applied across an anti-fuse such that the dielectric of the anti-fuse breaks down and allows current to pass through. In this manner, a selector switch SWₙ, when activated (turned on), facilitates the programming of a corresponding anti-fuse AFₙ. In other words, a particular anti-fuse is referred to as trimmed or programmed when the anti-fuse breaks down and allows a substantial flow of current.

In operation, trimming block 116 may be programmed through the HV drain terminal 104. During trimming or programming operation, isolation block 114 is turned “on” to couple the medium voltage appearing at node 129 to node 138 in trimming block 116. To program a selected anti-fuse AF, the gate of the corresponding selector switch SW is turned “on” by raising the gate to a high potential while the source is coupled to ground. All of the other selector switches SW (associated with unselected anti-fuses) are off (e.g., gate grounded with their sources coupled to ground through a high-impedance). In this manner, the anti-fuse coupled to the selector switch that is turned “on” is programmed due to the potential voltage difference across the selected anti-fuse AF. In operation, only one anti-fuse may be programmed at a time. However, a high voltage (e.g., 50 V) is still applied at the top plate of all the anti-fuses. All of the selector switches corresponding to unselected anti-fuses are turned “off”. In certain situations, an unintentional programming of unselected anti-fuses may occur due to capacitive coupling of anti-fuse AF capacitance and the drain to source capacitance of its corresponding selector switch SW. A soft clamp circuit SC may be coupled in parallel with each anti-fuse AF to prevent an unintentional programming of an anti-fuse AF, as will be discussed in further detail below.

In operation, one anti-fuse AF may be trimmed at a time. During the trimming process, also referred to as programming of one or more anti-fuses, low voltage (LV) controller 112 may output an address signal U_{ADD}. In operation, address signal U_{ADD} activates a selector switch SWₙ in trimming circuit block 116 so that its corresponding anti-fuse may be programmed. More specifically, an address signal U_{ADD} is delivered to a corresponding selector switch SW that corresponds with the anti-fuse AFₙ that has been selected to be programmed or trimmed. In this manner, LV controller 112 and a decoder 166 may output address signal U_{ADD} to isolate and trim a selected anti-fuse AF.

For example, selected anti-fuse AF₁ in trimming circuit block 116 may be programmed by turning on the corresponding selector switch SW₁ and then applying a voltage pulse at node 138 (e.g., 30-35 V for 2-5 ms) that allows a current of about 0.5 mA to 1.0 mA. The minimum voltage required to program the anti-fuse may depend on the gate oxide thickness. In one example, an gate oxide thickness of the anti-fuse AF may be 25 nm. Application of a pulse voltage greater than a breakdown voltage across the anti-fuse AF₁ for a certain time duration causes the gate oxide of the anti-fuse structure to rupture, resulting in a low impedance pathway between the top and bottom plate of the anti-fuse AF₁, with a resistance typically on the order of a few thousand ohms. The state of anti-fuse AF₁ can later be read by sensing its resistance by read block 126. As described throughout this disclosure, the pulse voltage utilized to trim the anti-fuses AF may be provided externally through the HV drain terminal 104.

As shown, each of the soft clamp circuits SC₁-SCₙ are electrically coupled in parallel with a corresponding one of the anti-fuse elements AF₁-AFn. As shown, soft clamp SC₁ is electrically coupled across anti-fuse AF₁, and so on. During a trimming operation, each soft clamp circuit SC functions to prevent unintentional programming of an anti-fuse (not selected for trimming) by clamping the voltage that appears across the corresponding anti-fuse element AF. Practitioners will understand that when programming a particular anti-fuse, the top plates of all the anti-fuses coupled to node 138 are simultaneously taken to a medium voltage (e.g., ˜50 V).

When the selector switch of an unselected anti-fuse AF is off, the voltage of the lower plate of the anti-fuse AF ideally follows the voltage applied to the upper plate via capacitive coupling. However, when the drain to source capacitance of a selector switch is relatively large (compared to the capacitance of the anti-fuse C_{AF}) there is a risk that the tracking of voltage for the lower capacitive plate may be significantly limited. In other words, the lower plate of the anti-fuse AF may not track or follow the voltage on the upper capacitive plate due to a larger drain-to-source capacitance of selector switch SW₁ coupled in series with anti-fuse AF. This may prevent the lower plate from tracking of voltage of the upper plate of anti-fuse AF, in which case the anti-fuse structure may be exposed to a large voltage differential. This may cause a small current to flow through the anti-fuse that will charge the bottom plate. This voltage difference may cause an unintentional programming of an unselected anti-fuse AF.

To alleviate this potential risk, in one embodiment, a soft clamp SC device is coupled across each corresponding anti-fuse AFₙ. In one example, each soft clamp SC may be a PMOS transistor comprising a polysilicon layer that covers a relatively thick field oxide layer and is utilized to clamp the voltage of an unselected anti-fuse.

During an initial start-up of high voltage IC 100, read block 126 is coupled to trimming circuit block 116 to determine which anti-fuse elements AFₙ have been programmed (typically during a trimming phase). In this manner, LV controller 112 may make adjustments to operating characteristics of high voltage IC 100. In operation, supply pin 118 provides power to internal circuitry in high voltage IC 100. In one example, supply pin 118 may be coupled to a supply capacitor that is charged by HV drain terminal 104 via tap element 108. In operation, feedback terminal 120 provides information to LV controller 112 such that it may drive high voltage switch 102. In one example, high voltage IC 100 is used in a switch mode power supply and high voltage switch 102 regulates the transfer of energy by limiting a current through the primary winding of a coupled inductor or a transformer.

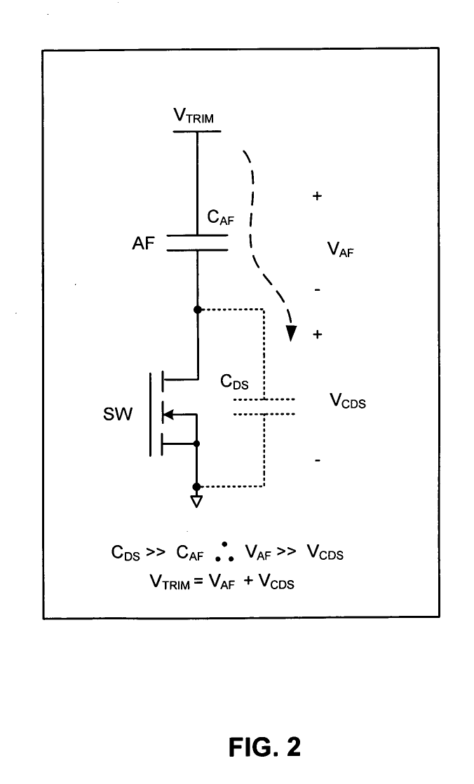

FIG. 2 is an example of a trimming element including an anti-fuse AFn coupled in series with a corresponding selector switch SWn. As shown, when a trimming voltage VTRIM is applied to the trimming element, the trimming voltage becomes the sum of a voltage across the anti-fuse V_{AF} and a voltage across the drain to source of the selector switch V_{CDS}.

Depending on the properties of the selector switch SW, a drain-to-source capacitance of the selector switch C_{DS} may be substantially larger than a capacitance of the anti-fuse C_{AF}. Since the anti-fuse AF and selector switch SW are coupled in series, the trimming voltage V_{TRIM} is distributed proportionately relative to the respective capacitances. In other words, when the drain-to-source selector switch capacitance C_{DS} is greater than anti-fuse capacitance C_{AF}, a substantial portion of trimming voltage is dropped across anti-fuse AF with respect to the amount of voltage is dropped across the selector switch SW.

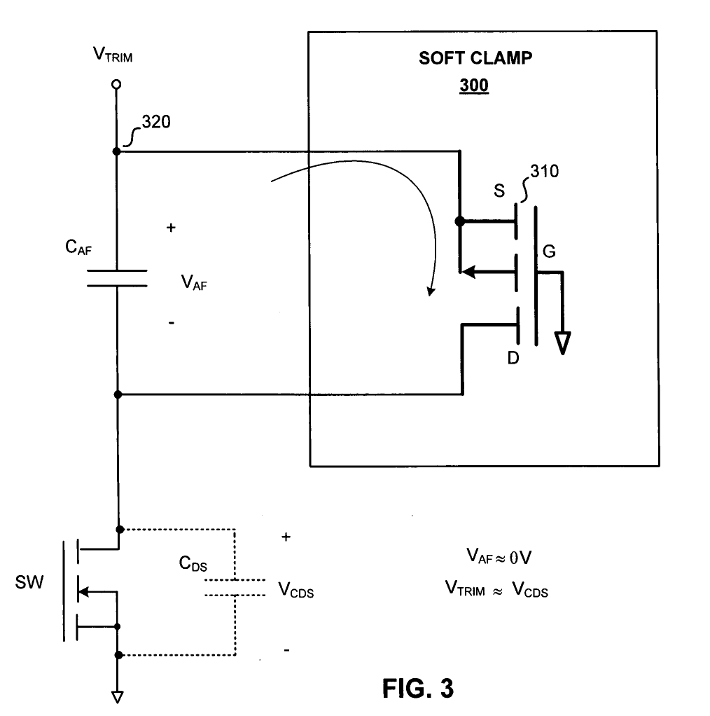

FIG. 3 illustrates an example soft clamp 300 coupled to a trimming element. To prevent an inadvertent programming of an unselected anti-fuse AF, a soft clamp 300 is coupled across each unselected anti-fuse element. In one example, soft clamp device element 300 may comprise, but is not limited to, a PMOS transistor. By way of example, the PMOS transistor with a high threshold voltage (15 V-20 V) utilized as a soft HV clamp device element may comprise a PMOS transistor 310 having, for example, a breakdown voltage of approximately 55-60V. The gate of the PMOS transistor may be connected to ground potential. During trimming or programming of anti-fuses, when a node 320 (similar to node 138 in FIG. 1) goes higher than a threshold voltage of the PMOS transistor a small current, e.g., a few microamperes, flows between the source and drain of PMOS transistor 310. For the particular anti-fuse which is being programmed this current is added to the trim current that flows through the anti-fuse (500 μA-1 mA). For the remaining group of unselected anti-fuses, this low current charges the bottom capacitive plate, thereby reducing the voltage build-up across each of the unselected anti-fuses AF.

In one example, when reading the anti-fuses AF, the voltage at node 320 does not exceed ˜12 V, so each of soft clamp device elements SC₁-SCₙ are off. Since, a reading of the anti-fuses AF requires a certain voltage (approximately 15 V) at node 320 (corresponds to node 138 in FIG. 1), the threshold voltage for PMOS transistor 310 must be greater than the voltage required at node 320. More specifically, if the threshold voltage of PMOS transistor 310 is not greater than the voltage applied at node 320 during the reading operation, the soft clamps SC coupled across corresponding untrimmed anti-fuses may be unintentionally activated thus indicating to controller 112 that the untrimmed anti-fuses have been trimmed. At the same time, the threshold voltage of PMOS transistor 310 may not exceed the break down voltage of the anti-fuses. In one example, a threshold voltage for PMOS transistor 310 may be between 10 V and 20 V.

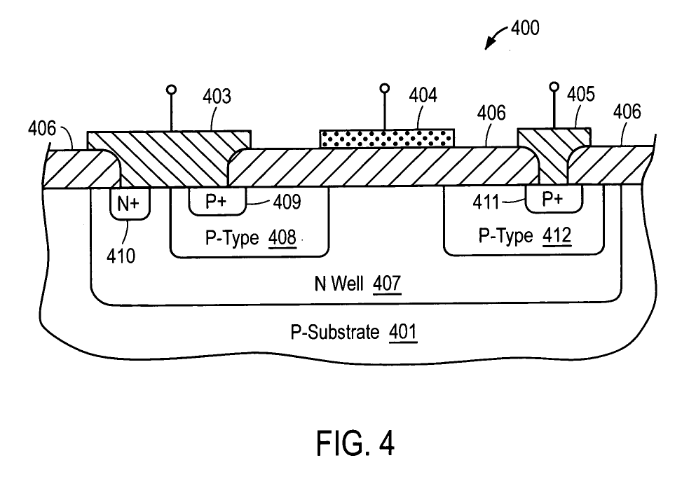

FIG. 4 illustrates an example cross-section of a soft high-voltage (HV) clamp device structure comprising a PMOS transistor 400 suitable for use as a soft clamp SC in high voltage IC 100 of FIG. 1 and soft clamp 300 of FIG. 3. As shown, a polysilicon layer 404, which forms the gate of PMOS transistor 400, is shown disposed on a thick field oxide layer 406 over the area of N well region 407 between P-type regions 408 & 412. N-well region 407 is disposed in P-type substrate 401. It is appreciated that N-well 407 of PMOS transistor 400 is separate from any N-well used to form the anti-fuse structures. An N+ region 410 is also disposed in N-well region 407 to electrically connect N-well region 407 to source electrode 403. A P+ source region 409, which is disposed in P-type region 408, is also electrically connected to source electrode 403. A P+ drain region 411 disposed in P-type region 412 is shown electrically connected to drain electrode 405.

It is further appreciated that the gate capacitance of transistor 400 is substantially lower as compared to the capacitance of anti-fuse AF due to the relative thickness of field oxide layer 406. In one embodiment, the threshold voltage of transistor 400, which is largely determined by the thickness of field oxide layer 406, is approximately 15-20 V. The drain-to-source breakdown voltage of PMOS transistor 400 is greater than 50 V. According to the present invention, the high threshold voltage is determined by the thickness of the field oxide layer 406. In one example, the thickness of the oxide layer of transistor 400 may be between (600-1000 nm).

Although the present invention has been described in conjunction with specific embodiments, those of ordinary skill in the arts will appreciate that numerous modifications and alterations are well within the scope of the present invention. Accordingly, the specification and drawings are to be regarded in an illustrative rather than a restrictive sense.

I claim:

1. A semiconductor device for protection of an anti-fuse (AF) element of a high-voltage integrated circuit (HVIC), the AF element having first and second capacitive plates, the semiconductor device comprising:
a substrate of a first conductivity type;
a first well region of a second conductivity type disposed in the substrate;
first and second regions of the first conductivity type disposed in the first well region, the first region being laterally separated by a channel region from the second region, the first region comprising a source of a MOSFET and the second region comprising a drain of the MOSFET, the drain being coupled to the first capacitive plate of the AF element, and the source being coupled to the second capacitive plate of the AF element;
a first conductive layer that extends laterally over the channel region from the first region to the second region, the first conductive layer being insulated from the channel region by a first dielectric layer, the first conductive layer comprising a gate of the MOSFET;
wherein a gate capacitance of the MOSFET is substantially less than a capacitance of the AF element such that when a programming voltage is applied to the first capacitive plate of the AF element and the AF element is unselected for programming, a current flows through the MOSFET that charges the second capacitive plate, thereby reducing a voltage build-up across the AF element.

2. The semiconductor device of claim 1 wherein a threshold voltage of the MOSFET is substantially less than the programming voltage.

3. The semiconductor device of claim 1 wherein the MOSFET has a breakdown voltage greater than the programming voltage.

4. The semiconductor device of claim 1 wherein the first dielectric layer comprises a field oxide layer.

5. The semiconductor device of claim 1 wherein an oxide thickness of the MOSFET is substantially greater than an oxide thickness of the AF element:

6. The semiconductor device of claim 1 wherein the first conductive layer comprises polysilicon.

7. The semiconductor device of claim 1 wherein the programming voltage comprises a voltage pulse of approximately 50 V.

8. The semiconductor device of claim 1 wherein the first conductivity type is P-type and the second conductivity type is N-type.

9. The semiconductor device of claim 1 wherein the first well region is separated in the substrate from a second well region of the AF element, the second well region being of the second conductivity type.

10. A soft clamp semiconductor device for preventing inadvertent programming of an unselected anti-fuse (AF) element of a high-voltage integrated circuit (HVIC), the unselected AF element having first and second capacitive plates, the soft clamp semiconductor device comprising:
a substrate of a first conductivity type;
a first well region of a second conductivity type disposed in the substrate;
a source region of the first conductivity type disposed in the first well region, the source region being electrically coupled to the second capacitive plate;
a drain region of the first conductivity type disposed in the first well region laterally separated from the source region by a channel area of the first well region, the drain region being electrically coupled to the first capacitive plate;
an insulated gate disposed over the channel area, the drain region, source region, and the insulated gate comprising a MOSFET;
wherein a gate capacitance of the MOSFET is substantially less than a capacitance of the unselected AF element such that when a programming voltage is applied to the first capacitive plate, a current flows through the MOSFET that charges the second capacitive plate, thereby reducing a voltage build-up across the unselected AF element.

11. The soft clamp semiconductor device of claim 10 wherein a threshold voltage of the MOSFET is substantially less than the programming voltage.

12. The soft clamp semiconductor device of claim 10 wherein the MOSFET has a breakdown voltage greater than the programming voltage.

13. The soft clamp semiconductor device of claim 10 wherein the insulated gate is separated from the channel area by a dielectric layer.

14. The soft clamp semiconductor device of claim 1 further comprising:
a drain electrode electrically connected to the drain region;
a source electrode electrically connected to the source region; and
a third region of the second conductivity type disposed in the first well region, the third region being laterally separated from the second region and electrically connected to the source electrode.

15. The soft clamp semiconductor device of claim 10 wherein the insulated gate comprises polysilicon.

16. The soft clamp semiconductor device of claim 10 wherein the programming voltage comprises a voltage pulse of approximately 50 V.

17. The soft clamp semiconductor device of claim 1 wherein the first conductivity type is P-type and the second conductivity type is N-type.

18. The soft clamp semiconductor device of claim 1 wherein the first well region is separated in the substrate from a second well region of the unselected AF element, the second well region being of the second conductivity type.

19. A method for programming a selected anti-fuse (AF) element of a power integrated circuit (IC) device, comprising:
turning on an isolation transistor element to couple a first pin of the power IC to a common node of an AF block that includes the selected AF element and an unselected AF element, the selected AF element and the unselected AF element each including first and second capacitive plates separated by a dielectric layer, the first capacitive plate being coupled to the common node;
coupling the second capacitive plate of the selected AF element to ground;
applying a pulsed voltage to the first pin such that a programming voltage is applied to the first capacitive plate of the selected AF element, the programming voltage being high enough to cause a first current to flow through the selected AF element sufficient to destroy at least a portion of the dielectric layer, thereby electrically programming the first and second capacitive plates;
flowing a second current through a MOSFET having drain and source regions respectively coupled to the first and second capacitive plates of the unselected AF element, the second current charging the second capacitive plate, thereby reducing a voltage build-up across the unselected AF element.

20. The method of claim 20 wherein the MOSFET has a gate capacitance substantially less than a capacitance of the unselected AF element.

21. The method of claim 20 wherein the second current is substantially less than the first current.

22. The method of claim 20 wherein the MOSFET has a threshold voltage substantially less than the programming voltage, and a breakdown voltage greater than the programming voltage.

23. The method of claim 20 wherein the MOSFET comprises a PMOS device.
